(19) United States
(12) Patent Application Publication
(10) Pub. No.: US 2025/0364367 A1
(43) Pub. Date: Nov. 27, 2025

(54) DUAL LEVEL COLD PLATE FOR MULTIPLE SEMICONDUCTOR DIE MODULE

(71) Applicant: International Business Machines Corporation, Armonk, NY (US)

(72) Inventors: Christopher Muzzy, Burlington, VT (US); Monali Naresh Basutkar, Danbury, CT (US); Noah Singer, White Plains, NY (US); James Mansfield Crafts, Warren, VT (US)

(21) Appl. No.: 18/673,763

(22) Filed: May 24, 2024

(51) Int. Cl. H01L 23/473; H01L 23/367

(52) U.S. Cl. CPC H01L 23/473; H01L 23/367

(57) ABSTRACT

An apparatus that includes a cold plate adapted for thermal management of multiple semiconductor dies. The cold plate includes an upper level including a first plurality of channels that are adapted to allow a cooled fluid to flow therethrough, a lower level including a second plurality of channels that are adapted to allow the cooled fluid to flow therethrough, where the lower level is adjacent to the multiple semiconductor dies, and an airgap located between the upper level and the lower level.

### BACKGROUND

The present disclosure generally relates to semiconductors, and more particularly to an apparatus for heat dissipation from semiconductors.

When a semiconductor device conducts electrical current, heat is produced by internal resistance of the device. Often, semiconductor modules are cooled by air convection or fluid flow adjacent the semiconductor modules using heat sinks and heat spreaders, for example.

### SUMMARY

According to some embodiments of the disclosure, there is provided an apparatus that includes a cold plate adapted for thermal management of multiple semiconductor dies. The cold plate includes an upper level including a first plurality of channels that are adapted to allow a cooled fluid to flow therethrough, a lower level including a second plurality of channels that are adapted to allow the cooled fluid to flow therethrough, where the lower level is adjacent to the multiple semiconductor dies, and an airgap located between the upper level and the lower level.

According to some embodiments of the disclosure, there is provided a system for thermal management of multiple semiconductor dies. The system includes at least one cold plate. The cold plate includes an upper level including a first plurality of channels that are adapted to allow a fluid to flow therethrough, a lower level including a second plurality of channels that are adapted to allow the fluid to flow therethrough, where the lower level is adjacent to the multiple semiconductor dies, and an airgap located between the upper level and the lower level. The system also includes a first flow path to move the fluid to the at least one cold plate, and a second flow path to move the fluid away from the at least one cold plate. The system further includes a heat exchanger connected to the first flow path to move the fluid to the at least one cold plate and the second flow path to move the fluid away from the at least one cold plate, and at least one pump connected to the first flow path and the second flow path to move the fluid.

According to some embodiments of the disclosure, there is provided a method of cooling multiple semiconductor dies. The method includes providing a thermal management system for cooling the multiple semiconductor dies. The system includes at least one cold plate. The cold plate includes an upper level including a first plurality of channels that are adapted to allow a fluid to flow therethrough, a lower level including a second plurality of channels that are adapted to allow the fluid to flow therethrough, where the lower level is adjacent to the multiple semiconductor dies, and an airgap located between the upper level and the lower level. The system also includes a first flow path to move the fluid to the at least one cold plate, and a second flow path to move the fluid away from the at least one cold plate. The system further includes a heat exchanger connected to the first flow path to move the fluid to the at least one cold plate and the second flow path to move the fluid away from the at least one cold plate, and at least one pump connected to the first flow path and the second flow path to move the fluid. The method also includes pumping the fluid through the system.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 illustrates a top-down, see-through view of a dual level cold plate located on a multiple semiconductor die module, in accordance with embodiments of the present disclosure.

FIG. 2 illustrates a cross-sectional view of the dual level cold plate of FIG. 1 taken at dashed line 2-2 in FIG. 1, in accordance with embodiments of the present disclosure.

FIG. 3 illustrates a cross-sectional view of a portion of the dual level cold plate of FIG. 1 taken at dashed line 3-3 and at dashed line 3-3 in FIG. 4 in FIG. 1 showing fluid flow therethrough, in accordance with embodiments of the present disclosure.

FIG. 4 illustrates a top-down, close-up view of a portion of an upper level of the dual level cold plate with a cover removed, as indicated in FIG. 1 by dashed line 4-4, showing fluid flow therethrough, in accordance with embodiments of the present disclosure.

FIG. 5 illustrates a flow diagram of a method of thermally managing a system including a dual level cold plate, in accordance with embodiments of the present disclosure.

FIG. 6 illustrates a schematic view of a thermal management system that includes a dual level cold plate, in accordance with embodiments of the present disclosure.

FIG. 7 illustrates a flow diagram of a method of cooling multiple semiconductor dies, in accordance with embodiments of the present disclosure.

While the disclosure is amenable to various modifications and alternative forms, specifics thereof have been shown by way of example in the drawings and will be described in detail. It should be understood, however, that the intention is not to limit the disclosure to the particular embodiments described. On the contrary, the intention is to cover all modifications, equivalents, and alternatives falling within the spirit and scope of the disclosure.

### DETAILED DESCRIPTION

Aspects of the present disclosure relate generally to thermal regulation of semiconductor dies. More particularly, the present disclosure provides a dual level cold plate for thermal management of multiple semiconductor dies. While the present disclosure is not necessarily limited to such applications, various aspects of the disclosure can be appreciated through a discussion of various examples using this context.

When a semiconductor die conducts electrical current, heat is produced by internal resistance of the device. When the heating rate of a module (having a plurality of such semiconductor dies) exceeds the available heat dissipation, there is a risk of temperature rise affecting changes in electrical behavior, such that thermal damage could occur to portions of the module. Accordingly, it is important to provide adequate cooling for a semiconductor module, and to equalize temperatures as much as possible among dies or chips comprising a semiconductor module.

In liquid cooling systems for semiconductor dies, a temperature of the liquid/fluid increases as the heat from operation of the nearby semiconductor dies can be transferred to the liquid/fluid. This occurs as the liquid/fluid moves from an inlet side to an outlet side of the liquid cooling system. For example, the temperature change of fluid travelling across a cold plate under 100% load, assuming uniform die/chip temperature, increases linearly as travel distance increases. In direct attach systems, where the liquid cooling apparatus is directly attached to a backside of a semiconductor die (or chip), with a thermal interface material, the increased heat problem on the outlet side of the liquid cooling system can be increased. For multiple semiconductor die modules (i.e., muti-chip modules), this problem can be increased even further. Thermal performance of the semiconductor die can be limited based on a die that experiences a highest temperature. In such multiple semiconductor die modules, it is desirable to cool the multiple dies or chips at the same level. Over time, as some dies are consistently running at a higher temperature, there could be a thermal or operational degradation to the dies over their lifetime.

Temperature difference (ΔT) between a cooling mechanism and an operational temperature is a known driver for thermal performance, such that a higher ΔT for a downstream die in a multiple semiconductor die module leads to better thermal performance. Using a typical cold plate, which includes a single level, the ΔT possible for downstream dies can be reduced.

Specific details of embodiments of a dual level, liquid-or fluid-cooled cold plate are disclosed herein. The dual level, liquid-or fluid-cooled cold plate can be directly attached to a multiple semiconductor die module. The dual level, liquid-or fluid-cooled cold plate can include an upper level and a lower level that can be used to deliver similar temperature fluid over multiple dies that can be located upstream or downstream with regards to the liquid or fluid flow through the cold plate. The dual level, liquid-or fluid-cooled cold plate can utilize a circuit that can reverse the flow of the liquid or fluid based on the activity of (i.e., heat generated by) the dies that are being cooled.

Embodiments disclosed herein include a dual level, directly attached cold plate for a multiple semiconductor die module with an upper level and a lower level so that on an inlet side, half of fluid/liquid flowing through the cold plate is directed to the upper level. The cold plate includes a region between upstream dies and downstream dies that allows fluid/liquid in the upper level to flow to the lower level and fluid in the lower level to flow to the upper level. The levels extend between an inlet mixing region to an outlet mixing region. A fluid/liquid flow direction can be reversed from inlet to outlet based on a circuit that can control a pump/switch and monitors utilization of the multiple semiconductor die module that is being cooled by the cold plate. Conditions can be set based on semiconductor utilization that can cause activation of a pump/switch. For example, when utilization drops below a certain threshold, the pump/switch can reverse the fluid/liquid flow direction.

Embodiments of the present disclosure can include a cold plate with fluid/liquid flow for the thermal regulation of a multiple semiconductor die module which is directly attached to the backside of said die and features/channels/fins that have an upper cooling level and a lower cooling level separated by an air gap, which is insulating, with polymer standoffs that have low thermal conductivity. At a center of the cold plate, there is a transfer zone where the fluids in the upper and lower levels switch (or are exchanged) so that fluid that is still cool in the upper level can flow through the lower level over dies that are attached on a downstream side of the cold plate. Fluid/liquid flow through the cold plate can be reversed in direction in response to a circuit determining system usage is below a threshold. The multiple die count in the multiple semiconductor die module can be greater than two. The cold plate can be made of material with a thermal conductivity of greater than 350 watts per meter-Kelvin (W/mK).

Embodiments of the present disclosure can provide advantages that can be valuable to the semiconductor industry. An advantage of embodiments includes effective cooling of multiple semiconductor dies in a module. Another advantage of the embodiments includes more even cooling of the multiple semiconductor dies in the module.

Embodiments of the present disclosure include an apparatus that includes a cold plate adapted for thermal management of multiple semiconductor dies. The cold plate includes an upper level including a first plurality of channels that are adapted to allow a cooled fluid to flow therethrough, a lower level including a second plurality of channels that are adapted to allow the cooled fluid to flow therethrough, where the lower level is adjacent to the multiple semiconductor dies, and an airgap located between the upper level and the lower level. An advantage of such embodiments includes effective cooling of multiple semiconductor dies in a module. Another advantage of such embodiments includes more even cooling of the multiple semiconductor dies in the module.

Embodiments of the present disclosure include a system for thermal management of multiple semiconductor dies. The system includes at least one cold plate. The cold plate includes an upper level including a first plurality of channels that are adapted to allow a fluid to flow therethrough, a lower level including a second plurality of channels that are adapted to allow the fluid to flow therethrough, where the lower level is adjacent to the multiple semiconductor dies, and an airgap located between the upper level and the lower level. The system also includes a first flow path to move the fluid to the at least one cold plate, and a second flow path to move the fluid away from the at least one cold plate. The system further includes a heat exchanger connected to the first flow path to move the fluid to the at least one cold plate and the second flow path to move the fluid away from the at least one cold plate, and at least one pump connected to the first flow path and the second flow path to move the fluid. An advantage of such embodiments includes effective cooling of multiple semiconductor dies in a module. Another advantage of such embodiments includes more even cooling of the multiple semiconductor dies in the module.

Embodiments of the present disclosure include a method of cooling multiple semiconductor dies. The method includes providing a thermal management system for cooling the multiple semiconductor dies. The system includes at least one cold plate. The cold plate includes an upper level including a first plurality of channels that are adapted to allow a fluid to flow therethrough, a lower level including a second plurality of channels that are adapted to allow the fluid to flow therethrough, where the lower level is adjacent to the multiple semiconductor dies, and an airgap located between the upper level and the lower level. The system also includes a first flow path to move the fluid to the at least one cold plate, and a second flow path to move the fluid away from the at least one cold plate. The system further includes a heat exchanger connected to the first flow path to move the fluid to the at least one cold plate and the second flow path to move the fluid away from the at least one cold plate, and at least one pump connected to the first flow path and the second flow path to move the fluid. The method also includes pumping the fluid through the system. An advantage of such embodiments includes effective cooling of multiple semiconductor dies in a module. Another advantage of such embodiments includes more even cooling of the multiple semiconductor dies in the module.

It will be readily understood that the components of the present embodiments, as generally described and illustrated in the Figures herein, can be arranged and designed in a wide variety of different configurations. Thus, the following detailed description of the embodiments of the apparatus, system, method, and computer program product of the present embodiments, as presented in the Figures, is not intended to limit the scope of the embodiments, as claimed, but is merely representative of selected embodiments.

Reference throughout this specification to “a select embodiment,” “one embodiment,” or “an embodiment” means that a particular feature, structure, or characteristic described in connection with the embodiment is included in at least one embodiment. Thus, appearances of the phrases “a select embodiment,” “in one embodiment,” or “in an embodiment” in various places throughout this specification are not necessarily referring to the same embodiment. It should be understood that the various embodiments can be combined with one another, and that any one embodiment can be used to modify another embodiment.

As used in this application and in the claims, the singular forms “a,” “an,” and “the” include the plural forms unless the context clearly dictates otherwise. Additionally, the term “includes” means “comprises.”

The term “semiconductor die” generally refers to a die having integrated circuits or components, data storage elements, processing components, and/or other features manufactured on semiconductor substrates. For example, semiconductor dies can include integrated memory circuitry and/or logic circuitry. Semiconductor dies and/or other features in semiconductor die packages can be said to be in “thermal contact” with one another if the two structures can exchange energy through heat via, for example, conduction, convection and/or radiation. A person skilled in the relevant art will also understand that the technology can have additional embodiments, and that the technology can be practiced without several of the details of the embodiments described below with reference to the figures.

As used herein, the terms “vertical,” “lateral,” “upper,” “lower,” “up,” “down,” “upstream,” and “downstream” can refer to relative directions or positions of features in the semiconductor die assemblies in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down and left/right can be interchanged depending on the orientation.

The semiconductor devices and methods for forming the same, in accordance with embodiments of the present disclosure, can be employed in applications, hardware, and/or electronic systems. Suitable hardware and systems for implementing embodiments of the invention can include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings of embodiments of the invention provided herein, one of ordinary skill in the art will be able to contemplate other implementations and applications of embodiments of the invention.

As used herein, the terms “electronics rack”, “rack-mounted electronic equipment”, and “rack unit” are used interchangeably, and unless otherwise specified include any housing, frame, rack, compartment, blade server system, etc., having one or more heat generating components of a computer system or electronics system, and can be, for example, a stand-alone computer processor having high-, mid-or low-end processing capability. In one embodiment, an electronics rack can comprise a portion of an electronic system, a single electronic system or multiple electronic systems, for example, in one or more sub-housings, blades, books, drawers, nodes, compartments, etc., having one or more heat-generating electronic components disposed therein. An electronic system(s) within an electronics rack can be movable or fixed relative to the electronics rack, with rack-mounted electronic drawers and blades of a blade center system being two examples of electronic systems (or subsystems) of an electronics rack to be cooled.

“Electronic component” refers to any heat-generating electronic component of, for example, a computer system or other electronic system requiring cooling. By way of example, an electronic component can comprise one or more integrated circuit dies, and/or other electronic devices to be cooled, such as one or more electronics cards comprising a plurality of memory modules.

Further, as used herein, the terms “liquid-cooled structure,” “liquid-cooled cold plate,” and “cold plate” refer to thermally conductive structures having one or more channels (or passageways) formed therein or passing therethrough, which facilitate the flow of liquid coolant through the structure. A liquid-cooled structure can be, for example, a liquid-cooled cold plate. In one example, tubing is provided extending through the liquid-cooled structure. An “air-to-liquid heat exchanger” or “air-to-liquid heat exchange assembly” means any heat exchange mechanism characterized as described herein through which liquid coolant can circulate; and includes, one or more discrete air-to-liquid heat exchangers coupled either in series or in parallel. An air-to-liquid heat exchanger can comprise, for example, one or more coolant flow paths, formed of thermally conductive tubing (such as copper or other tubing) in thermal or mechanical contact with a plurality of air-cooled cooling fins. Size, configuration and construction of the air-to-liquid heat exchanger can vary without departing from the scope of the invention disclosed. Still further, “data center” refers to a computer installation containing one or more electronics racks to be cooled. As a specific example, a data center can comprise one or more rows of rack-mounted computer units, such as server units.

However, the concepts presented are readily adapted to use with other types of coolant. For example, the coolant can comprise a glycol solution, a brine, a fluorocarbon liquid, a liquid metal, or other similar coolant, or refrigerant, while still maintaining the advantages and unique features of the present disclosure.

It is to be understood that the present disclosure will be described in terms of a given illustrative architecture; however, other architectures, structures, substrate materials and process features and steps/blocks can be varied within the scope of the present disclosure. It should be noted that certain features cannot be shown in all figures for the sake of clarity. This is not intended to be interpreted as a limitation of any particular embodiment, or illustration, or scope of the claims.

The illustrated embodiments will be best understood by reference to the drawings, where like parts are designated by like numerals throughout. The following description is intended only by way of example, and simply illustrates certain selected embodiments of devices, systems, and processes that are consistent with the embodiments as claimed herein.

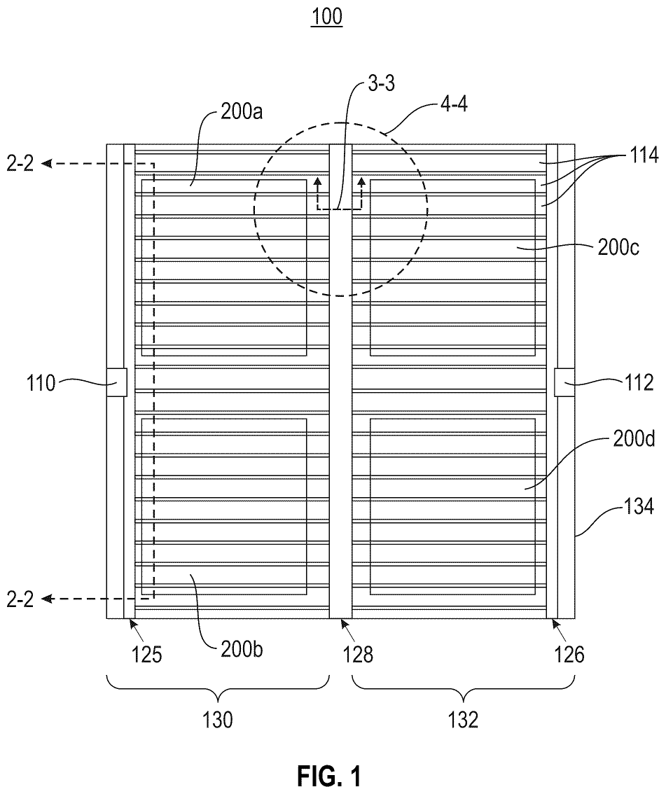

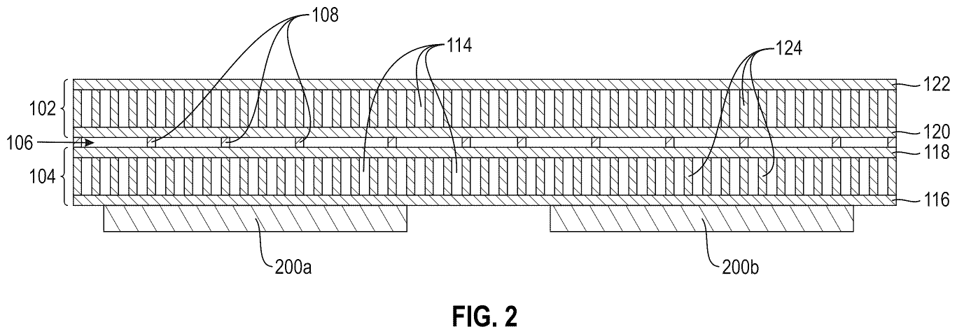

FIG. 1 illustrates a top-down, see-through view of a dual level cold plate 100 located on multiple semiconductor dies 200a, 200b, 200c, 200d (collectively referred to as a multiple semiconductor die module 200), and FIG. 2 illustrates a cross-sectional view of the dual level cold plate 100, located on the multiple semiconductor die module 200, of FIG. 1 taken at dashed line 2-2 in FIG. 1, both in accordance with embodiments of the present disclosure. The description of the dual level cold plate 100 below will be made with reference to both FIGS. 1 and 2.

As shown in FIGS. 1-2, the dual level cold plate 100 is a liquid-cooled cold plate that comprises an upper level 102 and a lower level 104 that are separated by an air gap 106 that includes a plurality of polymeric standoffs 108 to keep the upper level 102 and the lower level 104 separated or thermally isolated from each other. The air gap 106 with the polymeric standoffs 108 can be located between the lower level 104 and the upper level 102 in order to reduce (e.g., minimize) heat transfer from the lower level 104 to the upper level 102. The polymeric standoffs 108 can be made of any suitable polymer or any other suitable material that is low in thermal conductivity. Besides the polymeric standoffs 108, the dual level cold plate 100 can comprise a thermally conductive material, such as, for example, aluminum or copper.

The dual level cold plate 100 includes a cooled fluid input 110 and a warmed fluid output 112 that are located on opposite sides of dual level cold plate 100. Each of the upper level 102 and the lower level 104 include a plurality of channels 114 (or passageways) through which cooled input fluid and warmed output fluid flows. The channels 114 facilitate the flow of fluid, a liquid coolant, through the dual level cold plate 100. As fluid flows through the channels 114, it absorbs heat from the dual level cold plate 100. When warmed fluid exits the dual level cold plate 100, heat generated by the multiple semiconductor dies 200a-200d is physically removed from the dual level cold plate through the warmed fluid output 112. Tubing (not shown) can be attached to the cooled fluid input 110 and the warmed fluid output 112 in order to move fluid, e.g., liquid coolant, through the dual level cold plate 100.

The lower level 104 includes a lower-level floor 116 and a lower-level cover 118, and the upper level 102 include an upper-level floor 120 and an upper-level cover 122. The lower-level floor 116 can be in direct contact with the multiple semiconductor dies 200a-200d, as shown. A plurality of fins 124 extend both between the lower-level floor 116 and the lower-level cover 118 and between the upper-level floor 120 and the upper-level cover 122 in order to form the plurality of channels 114. The plurality of fins 124 increase the surface area of the dual level cold plate 100 thereby increasing the thermal transfer efficiency in order to help transfer heat from the multiple die module 200 to the fluid flowing through the dual level cold plate 100.

Cooled fluid can be injected into the cooled fluid input 110 and can enter an ingress manifold 125, or first mixing zone, which feeds the plurality of channels 114. The fluid flows through the plurality of channels 114 and absorbs heat from the underlying multiple semiconductor die module 200. The warmed fluid flows from each of the plurality of channels 114 then enters an egress manifold 126, or second mixing zone, and exits the dual level cold plate 100 from the fluid output 112. The ingress manifold 125 and the egress manifold 126 are located on opposite sides of the dual level cold plate 100. The arrangement of the cooled fluid input 110 and the warm fluid output 112 helps to force fluid flow into the ingress manifold 125 and from the egress manifold 126.

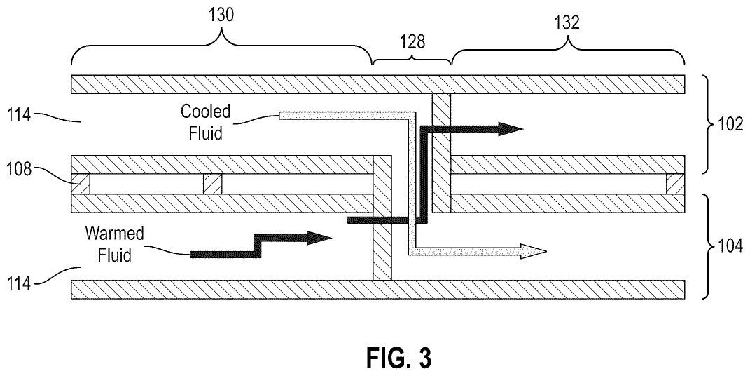

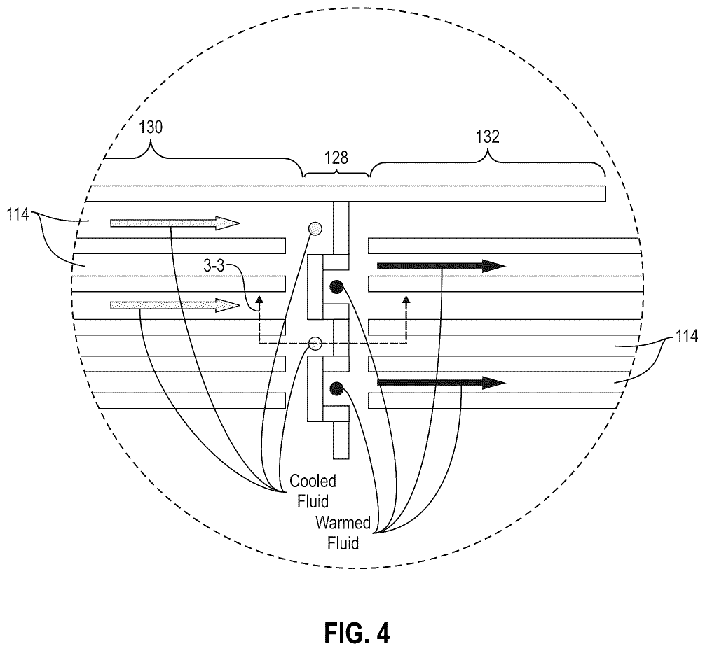

FIGS. 1, 3 and 4 show that in a middle or central region of the dual level cold plate 100, there can be a transfer zone 128 for transferring warmed fluid from the lower level 104 to the upper level 102 and cooled fluid from the upper level 102 to the lower level 104. The transfer zone 128 is fluidly connected to the first plurality of channels 114 (those in the upper level 102) and the second plurality of channels 114 (those in the lower level 104). The transfer zone 128 extends through the dual level cold plate 100 parallel to the direction of the plurality of channels 114. The transfer zone 128 allows warmed fluid to move from the lower level 104 on a first side 130 of the transfer zone 128 to the upper level 102 on a second side 132 of the transfer zone 128, and allows cooled fluid to move from the upper level 102 on the first side 130 of the transfer zone 128 to the lower level 104 on the second side 132 of the transfer zone 128. The arrows in FIGS. 3-4 show the fluid flow through the channels 114. The transfer zone 128 can be configured to enable/allow/facilitate the exchange of warmed fluid from the lower level 104 with cooled fluid from the upper level 102 and vice versa. For example, fluid that was warmed by a first set (or portion) of dies (dies 200a, 200b) on the first side 130 of the transfer zone 128 in the lower level 104 can be moved upward to the upper level 102 in order to then flow through the upper level 102 on second side 132 of the transfer zone 128, and cooled fluid from the upper level 102 on the first side 130 can be moved downward to the lower level 104 in the transfer zone 128 in order to the flow through the lower level 104 on the second side 132 to contact a second set of dies (dies 200c, 200d) on the second side 132. The exchange of fluid allows for more effective cooling of the second set of dies (dies 200c, 200d) such that fluid contacting a leading edge of the second set of dies (dies 200c, 200d) can be approximately the same temperature as fluid contacting a leading edge of the first set of dies (dies 200a, 200b).

FIG. 3 illustrates a cross-sectional view of a portion of the dual level cold plate 100 of FIG. 1 taken at dashed line 3-3 in FIG. 1 and at dashed line 3-3 in FIG. 4 showing fluid flow therethrough, in accordance with embodiments of the present disclosure. The figure includes a gray arrow that indicates movement of the “Cooled Fluid” from the upper level 102 on the first side 130 to the lower level 10 on the second side 132. Black arrows indicate movement of the “Warmed Fluid,” and extend into the page (e.g., to illustrate depth difference between the gray arrow and the black arrows). The “Warmed Fluid” is shown moving from the lower level 104 on the first side 130 to the upper level 102 on the second side 132.

FIG. 4 illustrates a top-down, close-up view of a portion of the upper level 102 of the dual level cold plate 100 with the upper-level cover 122 removed, as indicated in FIG. 1 by dashed line 4-4, showing fluid flow therethrough, in accordance with embodiments of the present disclosure. As shown, the arrows labelled “cooled fluid” show movement of the “cooled fluid” through the upper level 102 on the first side 130 of the transfer zone 128. The circles, in the transfer zone 128, labelled “cooled fluid” show the downward movement of the “cooled fluid” into the lower level (not shown) below. The circles labelled “warmed fluid” in the transfer zone 128 show the upward movement of the “warmed fluid” into the upper level 102 from the lower level (not shown) and the arrows labeled “warmed fluid” show movement of the warmed fluid through the upper level 102 on the second side 132 of the transfer zone 128.

Referring back to FIG. 1, a perimeter 134 of the dual level cold plate 100 can provide a metal-to-metal connection between the upper level 102 and the lower level 104. Also, shown in the figure are four (4) chips or dies in the multiple semiconductor die module 200, although other suitable numbers of dies or chips are also contemplated by the present disclosure.

Optionally, there can be other cooling elements, such as air-cooling elements located above the upper level 102 of the dual level cold plate 100. For example, a heat sink could be used as an addition cooling element, if the surrounding environment had air (ambient temperature) that is cool enough.

In some embodiments, the dual level cold plate 100 can have fluid flow therethrough reversed if certain conditions exist. Fluid flow can be reversed such that fluid output 112 becomes an input instead, and the fluid input 110 becomes an outlet instead. A system including the dual level cold plate 100 can alternate the direction (forward and reverse) of fluid flow. This can enable selectively cooling particular sides (e.g., the first side 130 and the second side 132) first. For example, in some embodiments, by controlling fluid flow direction, the second side 132, including dies 200c, 200d, can be exposed to the cooled fluid first. Alternatively, in some embodiments, by controlling fluid flow direction, the first side 130, including dies 200a, 200b, can be exposed to cooled fluid first. This can be desired in cooling a set of multiple semiconductor dies, such as dies 200a-200d, if the dual level cooling, such as that described above with regards to FIGS. 1-4, does not result in fluid being transferred in the transfer zone 128 from the upper level 102 to the lower level 104 having a temperature that matches (or is approximately similar to) an inlet temperature, or that of fluid in the first mixing zone, or ingress manifold 125. An advantage of the dual level cold plate 100 described can be equal or nearly equal cooling of upstream and downstream dies in a thermal regulation, or management, system incorporating the dual level cold plate 100.

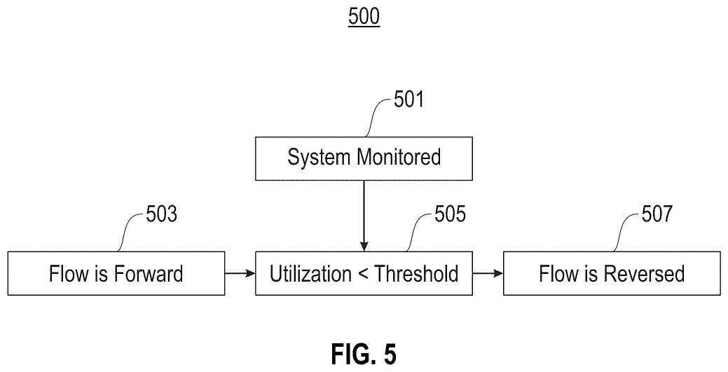

FIG. 5 illustrates a flow diagram of a method 500 of thermally managing a system including a dual level cold plate (such as the dual level cold plate 100), in accordance with embodiments of the present disclosure. The system can include a system utilization monitor that can monitor the system with regards to temperature of fluid moving through areas (e.g., near each of the dies underneath) of the dual level cold plate. The system utilization monitor can use a computer processing unit (CPU) or a memory subsystem or temperature of a combination of such features in order to determine when a reversal in the system needs to occur. Temperature can be detected in CPUs. Ambient temperature within a drawer, for example can be monitored. Outlet temperature of the cooling fluid can also be monitored. The method 500, accordingly, includes an operation 501 of the system being monitored. In another operation 503, flow through the system including the dual level cold plate is forward. In yet another operation 505, if utilization of the system results in cooling of downstream dies that is less than a threshold amount of cooling that is desired, then a further operation 507 results, such that flow through the dual level cold plate is reversed. If, however, utilization of the system results in cooling of downstream dies that is equal to or greater than a threshold amount of cooling that is desired, then the flow remains forward, as in the operation 503. Depending on the system, the reversal operation need not occur instantaneously. There can be a slight increase in temperature or reduction of cooling capability during that reversal of flow and for a period of time after the reversal takes place. In some embodiments, the method of thermally managing the system can include an increase or a decrease fluid flow speed by a pump based on conditions. In some embodiments, the system can include a system utilization monitor that can be configured to control a pump based on observed conditions in order to control direction and speed of fluid flow.

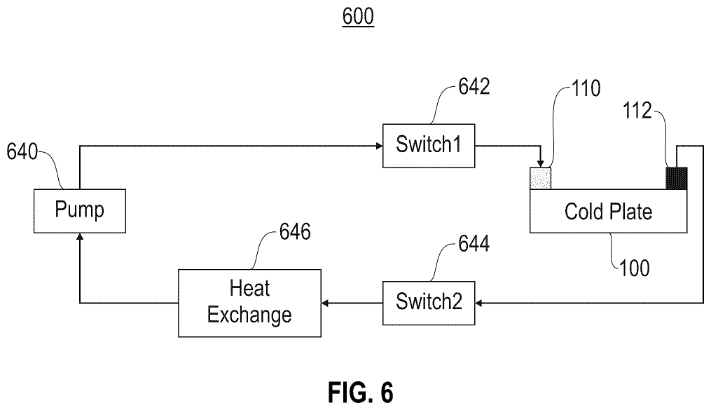

FIG. 6 illustrates a schematic view of a thermal management system 600 (e.g., a cooling system) that includes the dual level cold plate 100, in accordance with embodiments of the present disclosure. The thermal management system 600 shown is in a forward flow configuration. The thermal management system 600 shown includes a pump 640 that is joined to or fluidly connected to the dual level cold plate 100. A first switch 642 and a second switch 644, for example, can be used to control the system 600 to change between a forward flow configuration and a reverse flow configuration. After the fluid flows through the dual level cold plate 100, the fluid flow through a heat exchanger 646 and can be cooled to be returned to the dual level cold plate 100 again. Other suitable thermal management systems are also contemplated by the present disclosure that can utilize the dual level cold plate 100 disclosed herein.

The dual level cold plate 100 can be used on a single multiple semiconductor die module, such as the multiple semiconductor die module 200 as described above, and forward or reverse flow through a system (such as the thermal management system 600) can be applied to the single multiple die module 200. A manifold/switch on the pump 640 can change the direction on the pump, which is reversible. In other embodiments, the system (such as the thermal management system 600) described can be used on a single drawer or multiple drawers. For example, multiple drawers can each be fed from one or multiple pumps in series. A manifold/switch can be used at the drawer level which can change the direction of fluid flow within a drawer. A single pump can be used or multiple pumps can be used in parallel. Other suitable system configurations are also contemplated by the present disclosure.

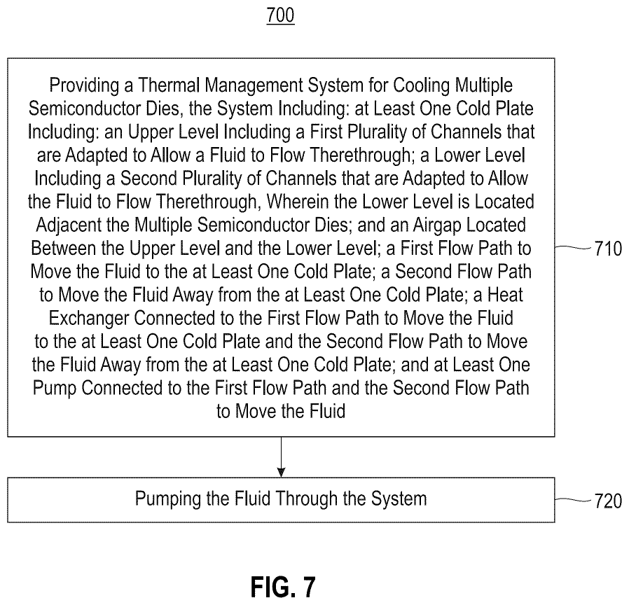

FIG. 7 illustrates a flow diagram of a method 700 of cooling multiple semiconductor dies, in accordance with embodiments of the present disclosure. An operation 710 of the method 700 can include providing a thermal management system for cooling the multiple semiconductor dies, the system including at least one cold plate. The at least one cold plate includes an upper level including a first plurality of channels that are adapted to allow a fluid to flow therethrough, a lower level including a second plurality of channels that are adapted to allow the fluid to flow therethrough, where the lower level is located adjacent the multiple semiconductor dies, and an airgap located between the upper level and the lower level. The system also includes a first flow path to move the fluid to the at least one cold plate, and a second flow path to move the fluid away from the at least one cold plate. The system further includes a heat exchanger connected to the first flow path to move the fluid to the at least one cold plate and the second flow path to move the fluid away from the at least one cold plate, and at least one pump connected to the first flow path and the second flow path to move the fluid. Another operation 720 can be pumping the fluid through the system.

With regard to the method 700 (not shown), the at least one cold plate can further include a fluid input to receive cooled fluid, an ingress manifold to feed the cooled fluid received from the fluid input to the first plurality of channels and the second plurality of channels, an egress manifold to collect warmed fluid from the first plurality of channels and the second plurality of channels, and a fluid output to emit the warmed fluid from the at least one cold plate. The at least one cold plate can further include a transfer zone located between the fluid input and the fluid output and between a first portion of the multiple semiconductor dies and a second portion of the multiple semiconductor dies, and fluidly connected to the second plurality of channels and the first plurality of channels, The transfer zone can be adapted to allow fluid flowing through the second plurality of channels located above the first portion of the multiple semiconductor dies to be transferred upward to the first plurality of channels located above the second portion of the multiple semiconductor dies and adapted to allow the fluid flowing through the first plurality of channels located above the first portion of the multiple semiconductor dies to be transferred downward to the second plurality of channels located above the second portion of the multiple semiconductor dies. The at least one cold plate can be adapted to allow fluid flow through the system to be reversed in direction in response to a circuit determining a difference in temperature between the second set of the multiple semiconductor dies and the first set of multiple semiconductor dies is above a threshold amount of temperature. The method 700 can further include operation of: determining the difference in temperature between the second set of the multiple semiconductor dies and the first set of multiple semiconductor dies is above the threshold amount of temperature and reversing a direction of fluid flow through the system. The at least one cold plate can further include: a plurality of polymeric standoffs located between the upper level and the lower level, where the plurality of polymeric standoffs are adapted to form the airgap.

For purposes of this description, certain aspects, advantages, and novel features of the embodiments of this disclosure are described herein. The disclosed processes, and systems should not be construed as being limiting in any way. Instead, the present disclosure is directed toward all novel and nonobvious features and aspects of the various disclosed embodiments, alone and in various combinations and sub-combinations with one another. The processes, and systems are not limited to any specific aspect or feature or combination thereof, nor do the disclosed embodiments require that any one or more specific advantages be present, or problems be solved.

Although the operations of some of the disclosed embodiments are described in a particular, sequential order for convenient presentation, it should be understood that this manner of description encompasses rearrangement, unless a particular ordering is required by specific language set forth below. For example, operations described sequentially can in some cases be rearranged or performed concurrently. Moreover, for the sake of simplicity, the attached figures may not show the various ways in which the disclosed processes can be used in conjunction with other processes. Additionally, the description sometimes uses terms like “provide” or “achieve” to describe the disclosed processes. These terms are high-level abstractions of the actual operations that are performed. The actual operations that correspond to these terms can vary depending on the particular implementation and are readily discernible by one of ordinary skill in the art.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

What is claimed is:

1. An apparatus comprising:
a cold plate adapted for thermal management of multiple semiconductor dies, the cold plate including:
an upper level including a first plurality of channels that are adapted to allow a cooled fluid to flow therethrough;
a lower level including a second plurality of channels that are adapted to allow the cooled fluid to flow therethrough, wherein the lower level is adjacent to the multiple semiconductor dies; and
an airgap located between the upper level and the lower level.

2. The apparatus of claim 1, wherein the cold plate further includes:
a plurality of polymeric standoffs located between the upper level and the lower level, wherein the plurality of polymeric standoffs are adapted to form the airgap.

3. The apparatus of claim 1, wherein the upper level and the lower level include a material with a thermal conductivity of greater than 350 W/mK.

4. The apparatus of claim 1, wherein the multiple semiconductor dies include a backside that are directly attached to the lower level.

5. The apparatus of claim 4, wherein the cold plate further includes:
a fluid input to receive the cooled fluid;
an ingress manifold to feed the cooled fluid received from the fluid input to the first plurality of channels and the second plurality of channels;
an egress manifold to collect warmed fluid from the first plurality of channels and the second plurality of channels; and
a fluid output to emit the warmed fluid from the cold plate.

6. The apparatus of claim 5, wherein the cold plate further includes:
a transfer zone located between the fluid input and the fluid output and between a first portion of the multiple semiconductor dies and a second portion of the multiple semiconductor dies, and fluidly connected to the second plurality of channels and the first plurality of channels,
wherein the transfer zone is adapted to allow fluid flowing through the second plurality of channels located above the first portion of the multiple semiconductor dies to be transferred upward to the first plurality of channels located above the second portion of the multiple semiconductor dies and adapted to allow the fluid flowing through the first plurality of channels located above the first portion of the multiple semiconductor dies to be transferred downward to the second plurality of channels located above the second portion of the multiple semiconductor dies.

7. The apparatus of claim 6, wherein the cold plate is adapted to allow fluid flow through the cold plate to be reversed in direction in response to a circuit determining a difference in temperature between the second portion of the multiple semiconductor dies and the first portion of multiple semiconductor dies is above a threshold amount of temperature.

8. A system for thermal management of multiple semiconductor dies, the system comprising:
at least one cold plate including:
an upper level including a first plurality of channels that are adapted to allow a fluid to flow therethrough;
a lower level including a second plurality of channels that are adapted to allow the fluid to flow therethrough, wherein the lower level is adjacent to the multiple semiconductor dies; and
an airgap located between the upper level and the lower level;
a first flow path to move the fluid to the at least one cold plate;
a second flow path to move the fluid away from the at least one cold plate;
a heat exchanger connected to the first flow path to move the fluid to the at least one cold plate and the second flow path to move the fluid away from the at least one cold plate; and
at least one pump connected to the first flow path and the second flow path to move the fluid.

9. The system of claim 8, wherein the at least one cold plate further includes:
a plurality of polymeric standoffs located between the upper level and the lower level, wherein the plurality of polymeric standoffs are adapted to form the airgap.

10. The system of claim 8, wherein the upper level and the lower level of the at least one cold plate is made of a material with a thermal conductivity of greater than 350 W/mK.

11. The system of claim 8, wherein the multiple semiconductor dies include a backside that are directly attached to the lower level of the at least one cold plate.

12. The system of claim 11, wherein the at least one cold plate further includes:
a fluid input to receive a cooled fluid;
an ingress manifold to feed the cooled fluid received from the fluid input to the first plurality of channels and the second plurality of channels;
an egress manifold to collect warmed fluid from the first plurality of channels and the second plurality of channels; and
a fluid output to emit the warmed fluid from the at least one cold plate.

13. The system of claim 12, wherein the at least one cold plate further includes:
a transfer zone located between the fluid input and the fluid output and between a first portion of the multiple semiconductor dies and a second portion of the multiple semiconductor dies, and fluidly connected to the second plurality of channels and the first plurality of channels,
wherein the transfer zone is adapted to allow fluid flowing through the second plurality of channels located above the first portion of the multiple semiconductor dies to be transferred upward to the first plurality of channels located above the second portion of the multiple semiconductor dies and adapted to allow the fluid flowing through the first plurality of channels located above the first portion of the multiple semiconductor dies to be transferred downward to the second plurality of channels located above the second portion of the multiple semiconductor dies.

14. The system of claim 13, wherein the cold plate is adapted to allow fluid flow through the thermal management system to be reversed in direction in response to a circuit determining a difference in temperature between the second portion of the multiple semiconductor dies and the first portion of multiple semiconductor dies is above a threshold amount of the temperature.

15. A method of cooling multiple semiconductor dies, the method comprising:
providing a thermal management system for cooling the multiple semiconductor dies, the system including:
at least one cold plate including:
an upper level including a first plurality of channels that are adapted to allow a fluid to flow therethrough;
a lower level including a second plurality of channels that are adapted to allow the fluid to flow therethrough, wherein the lower level is adjacent to the multiple semiconductor dies; and
an airgap located between the upper level and the lower level;
a first flow path to move the fluid to the at least one cold plate;
a second flow path to move the fluid away from the at least one cold plate;
a heat exchanger connected to the first flow path to move the fluid to the at least one cold plate and the second flow path to move the fluid away from the at least one cold plate; and
at least one pump connected to the first flow path and the second flow path to move the fluid; and
pumping the fluid through the system.

16. The method of claim 15, wherein the at least one cold plate further includes:
a fluid input to receive a cooled fluid;
an ingress manifold to feed the cooled fluid received from the fluid input to the first plurality of channels and the second plurality of channels;
an egress manifold to collect warmed fluid from the first plurality of channels and the second plurality of channels; and
a fluid output to emit the warmed fluid from the at least one cold plate.

17. The method of claim 16, wherein the at least one cold plate further includes:
a transfer zone located between the fluid input and the fluid output and between a first portion of the multiple semiconductor dies and a second portion of the multiple semiconductor dies, and fluidly connected to the second plurality of channels and the first plurality of channels,
wherein the transfer zone is adapted to allow fluid flowing through the second plurality of channels located above the first portion of the multiple semiconductor dies to be transferred upward to the first plurality of channels located above the second portion of the multiple semiconductor dies and adapted to allow the fluid flowing through the first plurality of channels located above the first portion of the multiple semiconductor dies to be transferred downward to the second plurality of channels located above the second portion of the multiple semiconductor dies.

18. The method of claim 17, wherein the at least one cold plate is adapted to allow fluid flow through the system to be reversed in direction in response to a circuit determining a difference in temperature between the second portion of the multiple semiconductor dies and the first portion of multiple semiconductor dies is above a threshold amount of temperature.

19. The method of claim 18, further comprising:
determining the difference in temperature between the second portion of the multiple semiconductor dies and the first portion of multiple semiconductor dies is above the threshold amount of temperature; and
reversing a direction of fluid flow through the system.

20. The method of claim 15, wherein the at least one cold plate further includes:
a plurality of polymeric standoffs located between the upper level and the lower level, wherein the plurality of polymeric standoffs are adapted to form the airgap.
